(19) United States
(12) Patent Application Publication
(10) Pub. No.: US 2006/0097630 A1
(43) Pub. Date: May 11, 2006

(54) Organic electroluminescent device and process for producing this same

(75) Inventors: Takanobu Shiokawa, Kanagawa (JP); Toru Chiba, Tokyo (JP); Takaomi Sekiya, Tokyo (JP); Hideo Fujii, Saitama (JP); Yukio Kubota, Saitama (JP)

Correspondence Address: GREENBLUM & BERNSTEIN, P.L.C., 1950 ROLAND CLARKE PLACE, RESTON, VA, 20191, US

(73) Assignee: PENTAX Corporation, Tokyo (JP)

(21) Appl. No.: 11/269,535

(22) Filed: Nov. 9, 2005

(30) Foreign Application Priority Data
Nov. 10, 2004 (JP) P2004-326296

(51) Int. Cl. H01J 1/62; H01J 63/04

(52) U.S. Cl. 313/504

(57) ABSTRACT

An EL device has an intermediate layer, one electrode layer, being one of an anode layer and a cathode layer, and an organic layer that are disposed on a substrate in sequence. The one electrode layer, the intermediate layer, and the substrate have light-transmitting properties. The organic layer emits light through the one electrode layer, the intermediate layer, and the substrate to outside the EL device. The refractive index of the intermediate layer is between a refractive index of the one electrode layer and a refractive index of the substrate.

### BACKGROUND OF THE INVENTION

1. Field of the Invention

The present invention is in relation to an organic electroluminescent and a process for producing the organic electroluminescent device.

2. Description of the Related Art

An organic electroluminescent device (hereafter “EL device”) has several properties that are superior to the properties of the other solid-state emitting devices, for example, having high response speed, having wide angle field of vision, and occupying a small space. Therefore, recently EL devices have been applied in various devices for example display devices, illumination devices, and so on.

An EL device is composed of an anode, an emitting layer, and a cathode which are disposed on a substrate in sequence. An electric current is input between the anode and the cathode so that the holes are injected from the anode, and the electrons are injected from the cathode. The injected holes and electrons are recombined in the emitting layer so as to emit light from the emitting layer. The emitted light is radiated through the anode and the substrate to outside the EL device as shown in U.S. Pat. No. 6,387,546.

However, the anode is formed of an electrically-conductive material, and the substrate is formed of an insulating material (for example glass), therefore, refractive index of the anode differs greatly that of the substrate. Due to the difference in these refractive indexes, reflection of the emitted light occurs at the interface between the anode and the substrate. This reflection causes a decrease in the electroluminescent efficiency of the EL device.

### SUMMARY OF THE INVENTION

Therefore, an object of the present invention is to provide an organic EL device having high electroluminescent efficiency and to provide a process for producing this device.

According to the present invention, there is provided an EL device, comprising an intermediate layer, one electrode layer being one of an anode layer and a cathode layer, and an organic layer that is disposed on a substrate in sequence. The one electrode layer, the intermediate layer, and the substrate have light transmitting properties. The organic layer emits light through the one electrode layer, the intermediate layer, and the substrate to outside the EL device. The refractive index of the intermediate layer is between a refractive index of the one electrode layer and a refractive index of the substrate in this invention. Due to this, the reflection between the one electrode layer and the organic layer can be decreased, compared with the case where the intermediate layer is not disposed. Therefore, the electroluminescent efficiency of the EL device can be improved.

The refractive index of the substrate is preferably lower than the refractive index of the one electrode layer. The refractive index of the intermediate layer is preferably a middle value of the refractive index of the one electrode layer and the refractive index of the substrate.

The refractive index of the intermediate layer changes according to its position in a layer-thickness direction for example. Namely, the refractive index of intermediate layer changes depending on its position in the lamination direction, or the layer-thickness direction for example of the EL device. In this case, the intermediate layer having a refractive index that is closer to the refractive index of the substrate, is preferably nearer to the substrate, and the intermediate layer having a refractive index that is closer to the refractive index of the one electrode layer, is preferably nearer to the one electrode layer. Due to this, the reflection between the one electrode layer and the organic layer can be decreased effectively.

Optionally the intermediate layer comprises a plurality of thin layers. In this case, the refractive index of each thin layer is different from that of the other thin layers for example. Of course, the refractive index of the intermediate layer can be changed gradually.

The intermediate layer preferably includes a material which forms the one electrode layer. More preferably, the intermediate layer is formed by a first material and second material, and the one electrode layer is formed by the first material. Due to this, if the intermediate layer and the one electrode layer are formed by using a double target sputtering device, the intermediate layer and the one electrode layer can be produced efficiently.

Optionally, the EL device comprises an anti-reflective layer, whose refractive index is lower than the refractive index of the substrate. The intermediate layer is disposed on one surface of the substrate, and the anti-reflective layer is disposed on another surface of the substrate. In this case, the refractive index of the anti-reflective layer is between the refractive index of the substrate and that of air, therefore the reflection at another surface of the substrate is decreased because the anti-reflective layer has the same functions as the intermediate layer.

The difference between the refractive index of the substrate and the refractive index of the anti-reflective layer is larger, as the anti-reflective layer is farther from the substrate. Due to this, the reflection at another surface of the substrate is efficiently decreased.

The device comprises another electrode layer that is disposed on the organic layer for example. The one electrode layer is an anode layer and the another electrode layer is cathode layer for example.

The transmittance of light to the outside in this invention is preferably higher than that when the device does not comprise the intermediate layer regarding light having a predetermined wavelength in a range from 400 nm to 500 nm, and having an exit angle of from 0° to 30°.

According to the present invention, there is provided a process for producing an EL device, comprising the steps of laminating an intermediate layer, one electrode layer being one of an anode layer and a cathode layer, and an organic layer on a substrate in sequence. The one electrode layer, the intermediate layer, and the substrate have light transmitting properties. The organic layer emits light through the one electrode layer, the intermediate layer, and the substrate to outside the EL device. In this invention, the refractive index of the intermediate layer is between a refractive index of the one electrode layer and a refractive index of the substrate.

The intermediate layer is formed by a first material and second material, and the one electrode layer is formed by the first material for example.

The process preferably comprises the steps of firstly sputtering the first material and the second material as double targets so as to laminate the intermediate layer which is formed of the first material and the second material on the substrate, and secondly sputtering the first material as a single target so as to laminate the one electrode layer which is formed by the first material on the intermediate layer.

### BRIEF DESCRIPTION OF THE DRAWINGS

The objects and advantages of the present invention will be better understood from the following description, with reference to the accompanying drawings in which:

FIG. 1 is a schematic cross sectional view of the EL device in a first embodiment,

FIG. 2 is a schematic cross sectional view of the EL device in a second embodiment,

FIG. 3 is a schematic cross sectional view of the EL device in a third embodiment,

FIG. 4 is a schematic cross sectional view of the EL device in a fourth embodiment,

FIG. 5 is a graph showing the transmittance for each wavelength of light which was radiated by the EL device in Comparative Example,

FIG. 6 is a graph showing the transmittance for each wavelength of light which was radiated by the EL device in Example 1,

FIG. 7 is a graph showing the transmittance for each wavelength of light which was radiated by the EL device in Example 2, and

FIG. 8 is a graph showing the transmittance for each wavelength of light which was radiated by the EL device in Example 3.

### DESCRIPTION OF THE PREFERRED EMBODIMENTS

The present invention will be described below with reference to the embodiments shown in the drawings.

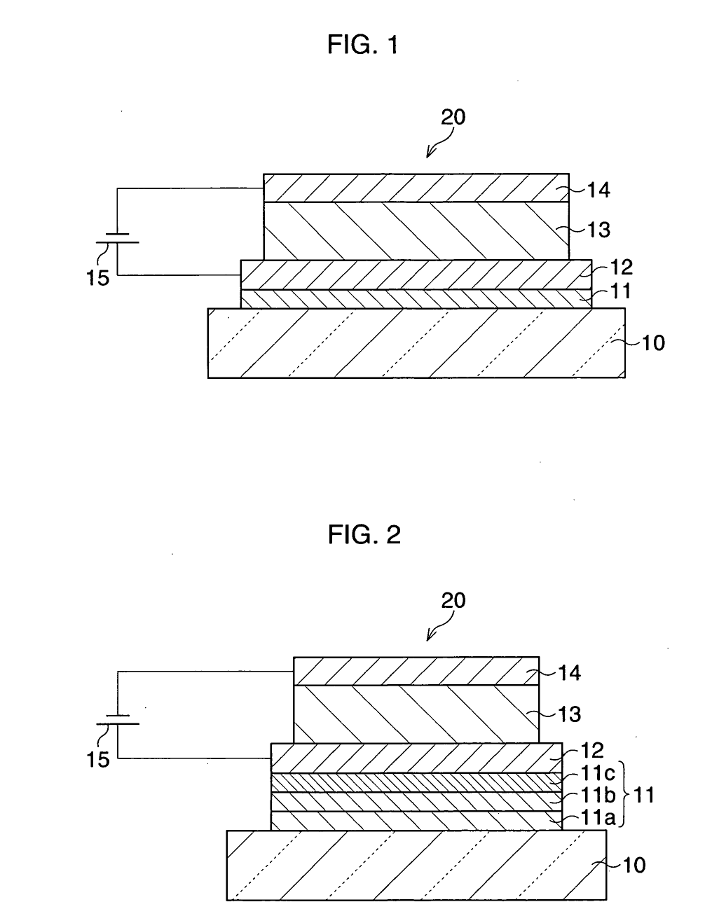

FIG. 1 shows an EL device, to which a first embodiment of the present invention is applied. The EL device 20 has a substrate 10, an intermediate layer 11 which lies on the substrate 10, an anode layer 12 (one electrode layer) which lies on the intermediate layer 11, an organic layer 13 which lies on the anode 12, and a cathode layer 14 (another electrode layer) which lies on the organic layer 13.

The substrate 10, which has light-transmitting properties, is formed by an insulating material for example glass, resin, plastic, and so on. The thickness of the substrate 10 is approximately from 100 □m to 1 cm. The anode layer 12 is formed by an electrically-conductive material having light-transmitting properties, for example ITO (Indium Tin Oxide), ATO (antimony doped tindioxide), ZnO (zinc oxide), and so on. In this embodiment, a refractive index of the anode layer 12 is higher than a refractive index of the substrate 10.

The intermediate layer 11 is formed by a mixture of a first material and a second material, and has light-transmitting properties. The first material has a refractive index which is the same as that of the material forming the anode layer 12 or which is close to that of the material forming the anode layer 12. The second material has a refractive index which is the same as that of the material forming the substrate 10 or which is close to that of the material forming the substrate 10. Due to this, the refractive index of the intermediate layer 11 is lower than the refractive index of the anode layer 12 and is higher than the refractive index of the substrate 10. In this embodiment, the refractive index of the intermediate layer 11 remains the same, when the position thereof in the layer-thickness direction is changed. Further, the layer-thickness direction is the lamination direction of each layer.

The first material is ITO, ATO, or ZnO for example, and is preferably the same as the material forming the anode layer 12. The second material has a refractive index that is lower than the refractive index of the first material, and the second material is preferably oxide, for example Al₂O₃, or SiO₂.

The refractive index of the intermediate layer 11 is preferably an arithmetic mean (a middle value) of the refractive index of the anode layer 12 and the refractive index of the substrate 10. In this case, if the first and second materials are the same as the material forming the anode layer 12 and the material forming the substrate 10 respectively, the ratio (mole ratio) of the first material to the second material is substantially 1:1.

The organic layer 13 has in sequence from the anode layer 12 side, a hole-transporting layer, an emitting layer, and an electron-transporting layer for example. The structure of the organic layer 13 is determined according to the purpose of the EL device 20, so that the organic layer 13 can emit green, red, blue, white or other color light. The refractive index of the organic layer 13 is preferably higher than that of the substrate 10 and is preferably lower than that of the anode layer 12.

The anode layer 12 and cathode layer 14, between which the organic layer 13 is located, are connected to a battery 15. The cathode 14 is preferably formed of metal, for example aluminum. When voltage is applied between the anode 12 and the cathode 14 from the battery 15, the organic layer 13 emits light.

The light emitted from the organic layer 13 radiates to outside the EL device 20 through the anode layer 12, the intermediate layer 11, and the substrate 10. The refractive index of one layer of the layers 10, 11, 12, and 13 is different from that of the other layers which are contacted therewith. Therefore, part of the light emitted from the organic layer 13 is reflected by each interface between two layers for the layers 10, 11, 12, and 13.

The refractive index of the anode layer 12 differs greatly from that of the substrate 10. Therefore, if the intermediate layer 11 was not disposed between the anode layer 12 and the substrate 10, a lot of the light emitted from the organic layer 13 would be reflected by the interface between the anode layer 12 and the substrate 10.

However, in this embodiment, the intermediate layer 11 having the refractive index which is between the refractive indexes of the anode layer 12 and the substrate 10 is disposed between the anode layer 12 and the substrate 10. Due to this, the differences of refractive index between two layers which contact each other become smaller, so that the reflection of the emitted light at the interfaces from the anode layer 12 to substrate 10 is decreased. Namely, the light emitted from the organic layer 13 is radiated outside the EL device 20 more efficiently than the case where the intermediate layer 11 is not disposed between the anode layer 12 and substrate 10. Therefore, the electroluminescent efficiency of the EL device 20 is improved in this embodiment.

Further, when the intermediate layer 11 is not disposed between the anode layer 12 and the substrate 10, the amount of the reflection from the anode layer 12 to the substrate 10 is relatively high in particular regarding light having a short wavelength in a range from 400 nm to 500 nm. However, the reflection regarding light in this range is decreased when the intermediate layer 11 is disposed between the anode layer 12 and substrate 10 in this embodiment. Namely, in this embodiment, the transmittance of from the anode layer 12 to the substrate 10 does not vary widely according to the changing the wavelength of light.

Next, the process for producing an EL device 20 will be explained. The case where the intermediate layer 11 is formed of the mixture of ITO and SiO₂ and the anode layer 12 is formed of ITO will be explained next. Of course the production process of this invention is not limited to the process explained in the next.

The intermediate layer 11 and the anode layer 12 are obtained by sputtering using a double target sputtering device for example. In this case, an ITO-target and a SiO₂-target are used as the double targets. Power is applied to each of these two targets from different power sources and the power applied to each target is controlled independently.

In this process, at first, the substrate 10 which has been washed is prepared. Next, power is applied to both the ITO-target and the SiO₂-target, and ITO and SiO₂ are sputtered on the substrate 10 so that the mixture of ITO and SiO₂ is laminated as the intermediate layer 11. After forming the intermediate layer 11, the power being supplied to the SiO₂-target is stopped and the power being supplied to the ITO-target is continued. Due to this, the sputtering is done by using only the ITO-target. Namely, the ITO-target as the single target is sputtered on the intermediate layer 11 so that only ITO is laminated as the anode layer 12. Next, the organic layer 13 is laminated on the anode layer 12 by vacuum evaporation and the cathode layer 14 is laminated on the organic layer 13 using a predetermined metal. Due to these processes, the EL device 20 is obtained.

In this process, the intermediate includes the first material (ITO) which forms the anode layer 12. Therefore, the intermediate layer 11 is produced efficiently well using the double target sputtering device.

FIG. 2 shows an EL device, to which a second embodiment of the present invention is applied. In FIG. 2, the same components in the first embodiment are given the same symbol.

In the second embodiment, the difference from the first embodiment is only the structure of the intermediate layer 11. Namely, in the first embodiment, the intermediate layer 11 is formed by a single layer in which the first and second materials are uniformly mixed so that the intermediate layer 11 has a uniform refractive index in the layer-thickness direction. On the other hand, in the second embodiment, the intermediate layer 11 is composed of a plurality of thin layers. Each thin layer has the different ratio (mole ratio) of the first material to the second material from that of the other thin layers. Therefore, the refractive index of each thin layer is different from that of the other thin layers.

Next, the structure of the intermediate layer 11 will be explained below in detail in the second embodiment. The intermediate layer 11 is composed of the first thin layer 11a, the second thin layer 11b, and the third thin layer 11c which are laid in sequence from the substrate 10 side. The first, second, and third thin layers 11a, 11b, and 11c are formed of a mixture of the first material (for example ITO) and the second material (for example SiO₂), as is similar to the first embodiment. The ratio (mole ratio) of the first material to the second material in the first thin layer 11a is the lowest and that in the third thin layer 11c is the highest in the intermediate layer 11. Therefore, the refractive index of the first thin layer 11a is the lowest and the refractive index of the third thin layer 11c is the highest in the intermediate layer 11.

Namely, the refractive index of each thin layer in the intermediate layer 11 is higher than that of the substrate 10 and lower than that of the anode layer 12. And the thin layers having refractive indexes that are relatively closer to the refractive index of the substrate 10, are located at a relatively nearer position to the substrate 10 in the layer-thickness direction of the EL device 20. And the thin layers having refractive indexes that are relatively closer to the refractive index of the anode layer 12, are located in a relatively nearer position to the anode layer 12 in the layer-thickness direction.

In the second embodiment, the difference in refractive index between two layers which contact each other is smaller than in the first embodiment. Therefore, the reflection at each interface between two layers which contact each other is decreased. Due to this, the loss of light caused by the reflection between the anode layer 12 to the substrate 10 is decreased, compared with the first embodiment. Further, in this embodiment, due to increasing the number of interfaces from the anode layer 12 to substrate 10, the emitting light is refracted many times from the anode layer 12 to substrate 10. Therefore, the transmittance from the anode layer 12 to the substrate 10 is almost the same even if the wavelength of the light is changed.

Further, the intermediate layer 11 has only three thin layers in this embodiment as described above. However, the intermediate layer 11 can have more than three thin layers or can have only two thin layers in this invention.

Next, the process for producing the EL device 20 will be explained in the second embodiment. As described below, this process is carried out using a double target sputtering device and using the ITO-target and the SiO₂-target as the double targets, similar to the first embodiment.

At first, the substrate 10 which has been washed is prepared. Next, power is applied to both the ITO-target and the SiO₂-target, and the mixture of ITO and SiO₂ is sputtered on the substrate 10 so that the mixture of ITO and SiO₂ is laminated as the first thin layer 11a. After that, the power supply to the SiO₂-target is lowered and the power supply to the ITO-target is raised, and ITO and SiO₂ is sputtered on the substrate 10 so that a mixture of ITO and SiO₂ is laminated as the second thin layer 11b. Due to this power adjustment, the ratio of ITO to SiO₂ in the second thin layer 11b is higher than that in the first thin layer 11a. The third thin layer 11c is laminated on the second thin layer 11b, similar to the second thin layer 11b. Next, the anode layer 12, the organic layer 13, and the cathode layer 14 are formed, similar to the first embodiment, so that the EL device 20 is obtained.

As described above, the intermediate layer 11 is formed efficiently using the double target sputtering device, similar to the first embodiment.

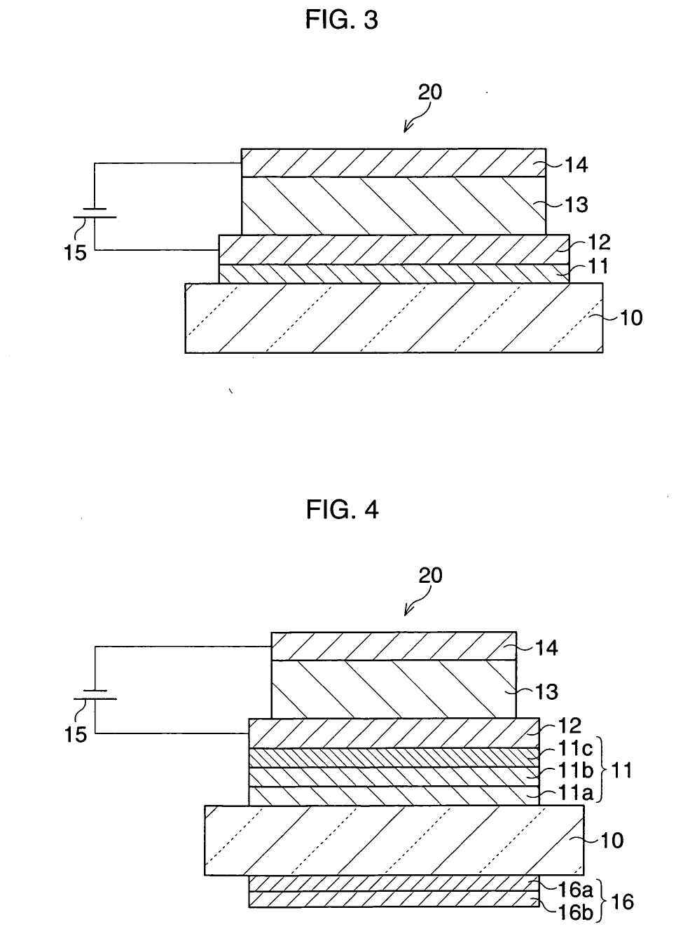

FIG. 3 shows an EL device, to which a third embodiment of the present invention is applied. The intermediate layer 11 in the third embodiment is composed of a single layer similar to the first embodiment. And, the side of the intermediate layer 11 having a refractive index that is closer to the refractive index of the substrate 10, is nearer to the substrate 10 in the layer-thickness direction, and the side of intermediate layer 11 having a refractive index that is closer to the refractive index of the anode layer 12, is nearer to the anode layer 12 in the layer-thickness direction, similar to the second embodiment.

In this embodiment, the refractive index of the intermediate layer 11 is changed gradually. Namely, the refractive index of the intermediate layer 11 is changed continuously to become the closer refractive index to that of the anode layer 12 as the intermediate layer 11 gets nearer to the anode layer 12.

Next, the process for producing the EL device 20 will be explained in the third embodiment. As described below, this process is carried out using a double target sputtering device and using the ITO-target and the SiO₂-target as the double targets, similar to the first and second embodiments.

First, the substrate 10 which has been washed is prepared. Next, power is applied to both the ITO-target and the SiO₂-target, and the mixture of ITO and SiO₂ starts to be sputtered on the substrate 10. In this case, the amount of power supplied to the SiO₂-target is maximum in this process, and the amount of power supplied to the ITO-target is minimum in this process. As the lamination of the mixture of ITO and SiO₂ progresses, the power supplied to the SiO₂-target is lowered gradually and the power supplied to the ITO-target is raised gradually. Finally, when the amount of power supplied to the SiO₂-target becomes minimum, and the amount of the power supplied to the ITO-target becomes maximum in this process, the lamination of the intermediate layer 11 is finished. After finishing the lamination of the intermediate layer 11, the ITO continues to be sputtered so as to laminate the anode layer 12, in the state where the amount of power supplied to the SiO₂-target is 0, and the amount of power supplied to the ITO-target is maximum. Next, the organic layer 13, and the cathode layer 14 are laminated in sequence on the anode layer 12 so that the EL device 20 is produced.

As mentioned above, the intermediate layer 11 of the third embodiment is also produced efficiently using the double target sputtering device.

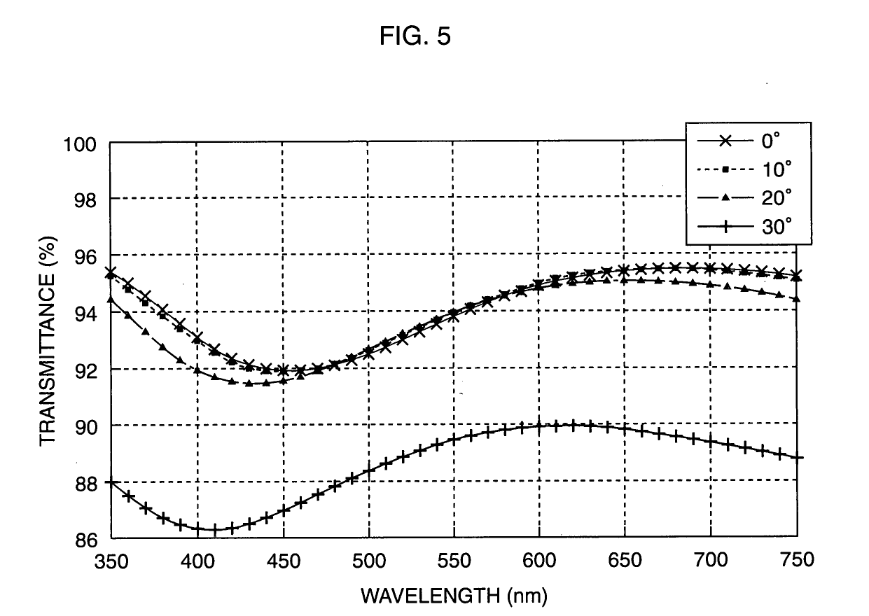

FIG. 4 shows an EL device, to which a forth embodiment of the present invention is applied. The difference in the forth embodiment from the second embodiment is that EL device 20 has an anti-reflective layer 16 whose refractive index is lower than that of the substrate 10. The differences from the second embodiment will be described next.

The EL device 20 has the intermediate layer 11, the anode layer 12, the organic layer 13, and the cathode layer 14 which are disposed on an upper surface of the substrate 10, similar to the second embodiment. The anti-reflective layer 16 is disposed on a bottom surface of the substrate 10.

The anti-reflective layer 16 includes a first anti-reflective layer 16a and a second anti-reflective layer 16b which are laminated on the bottom surface of the substrate 10 in this sequence. A refractive index of the first anti-reflective layer 16a is lower than that of the substrate 10 and a refractive index of the second anti-reflective layer 16b is lower than that of the first anti-reflective layer 16a. Namely, the difference in the refractive index between the anti-reflective layer 16 and substrate 10 is larger as the anti-reflective layer 16 is farther from the substrate 10 in the layer-thickness direction.

The first anti-reflective layer 16a is formed of MgF₂ for example and the second anti-reflective layer 16b is formed of silica aerogel for example. Further, the refractive index of the second anti-reflective layer 16b is higher than the refractive index (1.00) of air.

The refractive index of the anti-reflective layer 16 is between the refractive index of the substrate 10 and that of air. Further, the anti-reflective layer 16 has a lower refractive index as it gets farther from the substrate 10. Therefore, the anti-reflective layer 16 decreases the reflection at the bottom surface in the same way as the intermediate layer 11. Due to this, the electroluminescent efficiency of the EL device can be improved.

The EL device 20 of the fourth embodiment is produced, in a similar way to the second embodiment. In this case, the anti-reflective layer 16 is preferably laminated on the substrate 10 before the intermediate layer 11 and the anode layer 12 etc. are laminated on the substrate 10.

In this embodiment, the anti-reflective layer 16 is composed of two layers. However, the anti-reflective layer 16 can be composed of one layer or more than two layers.

Further, as described above, in the first to the fourth embodiments, the one electrode layer which is disposed between the organic layer 13 and the substrate 10 is the anode. However, the one electrode layer can be the cathode. Of course, in this case, another layer which is laid on the organic layer 13 is an anode.

### EXAMPLES

The present invention will be explained with reference to examples of the invention as well as comparative examples. Note that the present invention is not limited in any way by these examples.

The following Table 1 shows the structure of each layer of the EL device in Comparative Example 1. The Tables 2, 3, and 4 show the structure of each layer of the EL device used in Examples 1, 2, and 3 respectively.

In each Example, the intermediate layer was formed from a mixture of ITO and SiO₂ and the anode layer was formed from ITO. The organic layer was composed of the organic layer emitting white light and the substrate was composed of a glass base in each of the Examples. The cathode layer (not shown in Tables) was laid on the organic layer in each of the Examples.

TABLE 1
[Comparative Example]

| | | Refractive | Thickness | Mole Ratio | |
|---|---|---|---|---|---|
| | Material | Index | (nm) | ITO | SiO₂ |
| 0 | Organic Layer | 1.75 | — | — | — |
| 1 | Anode Layer | 2.00 | 170 | 100 | 0 |
| 2 | Substrate | 1.50 | — | — | — |
| 3 | Air | 1.00 | — | — | — |

TABLE 2
[Example 1]

| | | Refractive | Thickness | Mole Ratio | |
|---|---|---|---|---|---|
| | Material | Index | (nm) | ITO | SiO₂ |
| 0 | Organic Layer | 1.75 | — | — | — |
| 1 | Anode Layer | 2.00 | 170 | 100 | 0 |
| 2 | Intermediate Layer | 1.75 | 70 | 54 | 46 |
| 3 | Substrate | 1.50 | — | — | — |
| 4 | Air | 1.00 | — | — | — |

TABLE 3
[Example 2]

| | | Refractive | Thickness | Mole Ratio | |
|---|---|---|---|---|---|
| | Material | Index | (nm) | ITO | SiO₂ |
| 0 | Organic Layer | 1.75 | — | — | — |
| 1 | Anode Layer | 2.00 | 170 | 100 | 0 |
| 2 | Ninth Thin Layer | 1.95 | 64 | 90 | 10 |
| 3 | Eighth Thin Layer | 1.90 | 84 | 82 | 18 |
| 4 | Seventh Thin Layer | 1.85 | 86 | 72 | 28 |
| 5 | Sixth Thin Layer | 1.80 | 101 | 63 | 37 |
| 6 | Fifth Thin Layer | 1.75 | 89 | 54 | 46 |
| 7 | Fourth Thin Layer | 1.70 | 113 | 44 | 56 |
| 8 | Third Thin Layer | 1.65 | 78 | 35 | 65 |
| 9 | Second Thin Layer | 1.60 | 34 | 26 | 74 |
| 10 | First Thin Layer | 1.55 | 75 | 17 | 83 |
| 11 | Substrate | 1.50 | — | — | — |
| 12 | Air | 1.00 | — | — | — |

TABLE 4
[Example 3]

| | | Refractive | Thickness | Mole Ratio | |
|---|---|---|---|---|---|
| | Material | Index | (nm) | ITO | SiO₂ |
| 0 | Organic Layer | 1.75 | — | — | — |
| 1 | Anode Layer | 2.00 | 170 | 100 | 0 |
| 2 | Ninth Thin Layer | 1.95 | 64 | 90 | 10 |
| 3 | Eighth Thin Layer | 1.90 | 84 | 82 | 18 |
| 4 | Seventh Thin Layer | 1.85 | 86 | 72 | 28 |
| 5 | Sixth Thin Layer | 1.80 | 101 | 63 | 37 |
| 6 | Fifth Thin Layer | 1.75 | 89 | 54 | 46 |
| 7 | Fourth Thin Layer | 1.70 | 113 | 44 | 56 |
| 8 | Third Thin Layer | 1.65 | 78 | 35 | 65 |
| 9 | Second Thin Layer | 1.60 | 34 | 26 | 74 |
| 10 | First Thin Layer | 1.55 | 75 | 17 | 83 |
| 11 | Substrate | 1.50 | — | — | — |
| 12 | First Anti- | 1.38 | 99 | Formed by MgF₂ | |
| | reflective Layer | | | | |
| 13 | Second Anti- | 1.10 | 140 | Formed by Silica | |
| | reflective Layer | | | Aerogel | |
| 14 | Air | 1.00 | — | — | — |

Regarding light the radiated from the EL device, having an exit angle of 0°, 10°, 20°, and 30° at the interface between air and the substrate (or between air and the second anti-reflective layer), the transmittance was measured for each wavelength of the light, in each of the EL devices for the Comparative Example and Examples. In this case, the transmittance is the ratio of light which is radiated outside the EL device to light which the organic layer emits. Further, the thickness of the substrate was 3 mm in the Comparative Example and Examples 1-3.

The Comparative Example is an example of a conventional EL device. Namely, the EL device does not have the intermediate layer and the anode layer is laminated on the substrate directly as shown in Table 1.

The transmittance for each wavelength of light which was radiated by the EL device for the Comparative Example is shown in FIG. 5. As shown in FIG. 5, in Comparative Example, the transmittance of light having a wavelength in a range from 400 nm to 550 nm was particularly low.

Example 1 corresponds to the first embodiment, therefore the intermediate layer in the EL device of Example 1 was composed of the single layer. The refractive index of the intermediate layer (1.75) was an arithmetic mean of the refractive index of the anode layer (2.00) and the refractive index of the substrate (1.50). In this case, the intermediate layer was formed by the mixture of ITO and SiO₂, and the mole ratio of ITO to SiO₂ was 54:46.

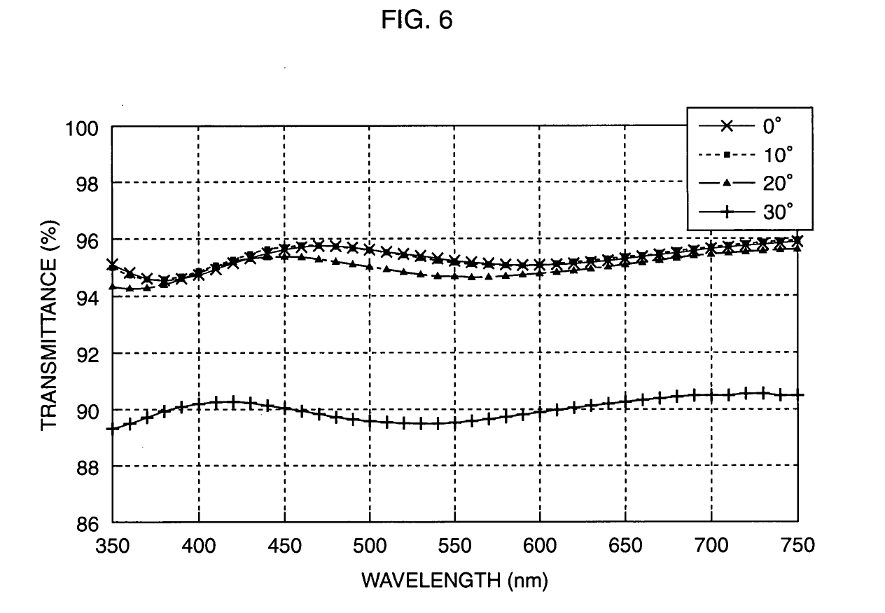

The transmittance for each wavelength of light which was radiated by the EL device of Example 1 is shown in FIG. 6. The transmittance of light having a wavelength in a range from 400 nm to 550 nm which was low in the Comparative Example was improved in Example 1 regarding the lights having an exit angle of 0°, 10°, and 20°. Further, regarding the lights having an exit angle of 30°, the transmittance of light having a wavelength in a range from 350 nm to 500 nm which was low in Comparative Example, was also improved in Example 1.

Namely, the transmittance in Example 1 was higher than that in the Comparative Example at least regarding the light having a wavelength in a range from 400 nm to 500 nm and having an exit angle of from 0° to 30°.

Furthermore, the transmittance in Comparative Example varied widely according to changes in the wavelength. On the other hand, the transmittance of Example 1 varied by less than that of the Comparative Example.

Example 2 corresponded to the second embodiment, therefore the intermediate layer in the EL device of Example 1 was composed of nine thin layers as shown in Table 3. The refractive index of thin layers got smaller as the thin layers got nearer to the substrate, in the layer-thickness direction. The nine thin layers were formed by gradually changing the mole ratio of ITO and SiO₂ as shown in Table 3.

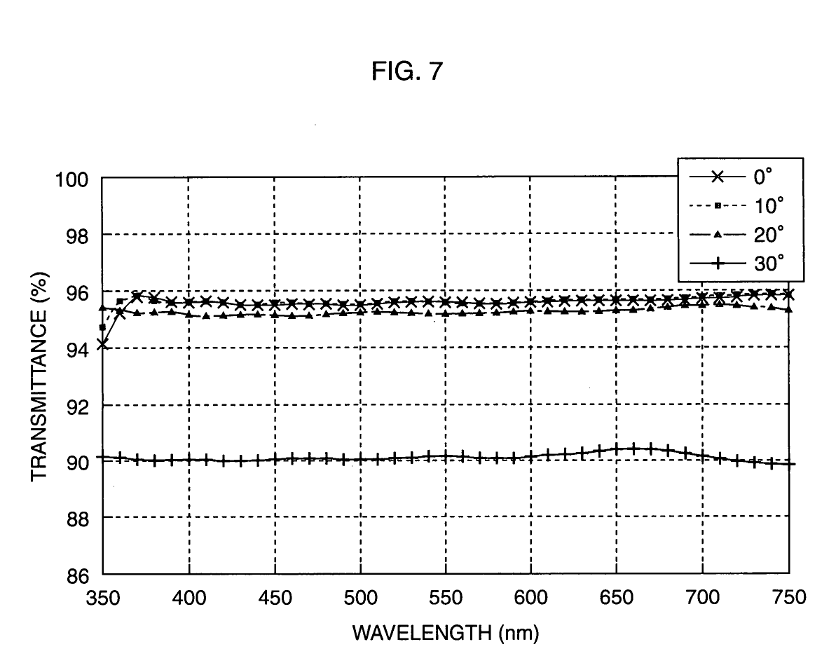

The transmittance for each wavelength of light which was radiated by the EL device for Example 2 is shown in FIG. 7. The transmittance was improved in Example 2 regarding the lights having an exit angle of 0°, 10°, 20°, and 30° and having a wavelength in a range from 350 nm to 750 nm, compared with that of the Comparative Example. In particular, the transmittance of light having a wavelength in a range from 400 nm to 500 nm which was low in the Comparative Example was dramatically improved in Example 2 regarding light having an exit angle of 0°, 10°, and 20°. Similarly, the transmittance of light having a wavelength in a range from 350 nm to 500 nm which was low in the Comparative Example was dramatically improved in Example 2 regarding light having an exit angle of 30°. Furthermore, the variance in transmittance in Example 2 was narrower according to changing wavelength, than in Example 1.

Example 3 corresponds to the fourth embodiment, therefore the EL device of Example 3 had an anti-reflective layer. In the Example 3, the intermediate layer was disposed on an upper surface of the substrate, similar to Example 2, and the anti-reflective layer which consisted of the first anti-reflective layer and the second anti-reflective layer was disposed on a bottom surface of the substrate. In Example 3, the first anti-reflective layer was formed of MgF₂ and the second anti-reflective layer was formed of silica aerogel.

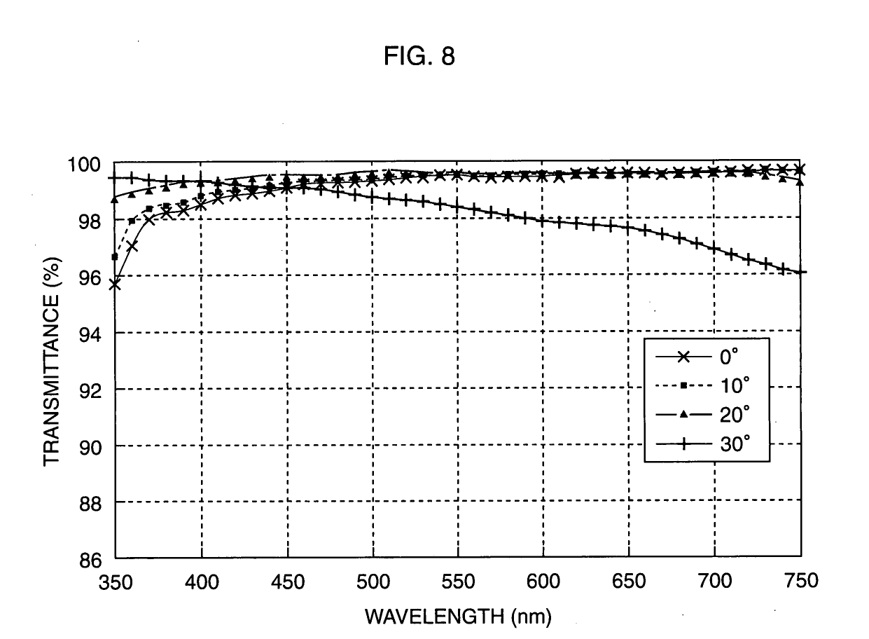

The transmittance for each wavelength of light which was radiated by the EL device of Example 3 is shown in FIG. 8. As shown in FIG. 8, the transmittance was improved in Example 3 regarding the lights having an exit angle of 0°, 10°, 20°, and 30° and having a wavelength in a range from 350 nm to 750 nm, compared with that of the Comparative Example. Furthermore, the transmittance regarding light having a wavelength in a range from 350 nm to 750 nm in Example 3 was also higher than that in Examples 1 and 2.

Although the embodiments of the present invention have been described herein with reference to the accompanying drawings, obviously many modifications and changes can be made by those skilled in this art without departing from the scope of the invention.

The present disclosure relates to subject matter contained in Japanese Patent Applications No. 2004-326296 (filed on Nov. 10, 2004) which is expressly incorporated herein, by references, in its entirety.

1. An organic electroluminescent device, comprising:
an intermediate layer, one electrode layer being one of an anode layer and a cathode layer, and an organic layer that are disposed on a substrate in sequence,
said one electrode layer, said intermediate layer, and said substrate having light-transmitting properties,
said organic layer emitting light through said one electrode layer, said intermediate layer, and said substrate to outside said organic electroluminescent device;
wherein a refractive index of said intermediate layer is between a refractive index of said one electrode layer and a refractive index of said substrate.

2. A device according to claim 1, wherein said refractive index of said substrate is lower than said refractive index of said one electrode layer.

3. A device according to claim 1, wherein said refractive index of said intermediate layer is an arithmetic mean of said refractive index of said one electrode layer and said refractive index of said substrate.

4. A device according to claim 1, wherein said refractive index of said intermediate layer is changed according to a position in a layer-thickness direction.

5. A device according to claim 4, wherein said intermediate layer having a refractive index that is closer to said refractive index of said substrate, is nearer to said substrate, and said intermediate layer having a refractive index that is closer to said refractive index of said one electrode layer, is nearer to said one electrode layer.

6. A device according to claim 5, wherein said intermediate layer comprises a plurality of thin layers, and a refractive index of each said thin layer is different from that of the other said thin layers.

7. A device according to claim 4, wherein said refractive index of said intermediate layer is changed gradually.

8. A device according to claim 1, wherein said intermediate layer includes a material which forms said one electrode layer.

9. A device according to claim 8, wherein said intermediate layer is formed by a first material and a second material, and said one electrode layer is formed by said first material.

10. A device according to claim 1, comprising an anti-reflective layer, a refractive index of said anti-reflective layer being lower than said refractive index of said substrate,
wherein said intermediate layer is disposed on one surface of said substrate, and said anti-reflective layer is disposed on another surface of said substrate.

11. A device according to claim 10, wherein a difference between said refractive index of said substrate and said refractive index of said anti-reflective layer is larger, as said anti-reflective layer is farther from said substrate.

12. A device according to claim 1, wherein said device comprises another electrode layer that is disposed on said organic layer.

13. A device according to claim 1, wherein a transmittance to said outside of light having a predetermined wavelength in a range from 400 nm to 500 nm, is higher than that when said device does not comprise said intermediate layer, said light having an exit angle of from 0° to 30°.

14. A process for producing an organic electroluminescent device, comprising the steps of:
laminating an intermediate layer, one electrode layer, being one of an anode layer and a cathode layer, and an organic layer on a substrate in sequence;
said one electrode layer, said intermediate layer, and said substrate having light-transmitting properties,
said organic layer emitting light through said one electrode layer, said intermediate layer, and said substrate to outside said organic electroluminescent device,
wherein a refractive index of said intermediate layer is between a refractive index of said one electrode layer and a refractive index of said substrate.

15. A process according to claim 14, wherein said intermediate layer is formed of a first material and second material, and said one electrode layer is formed of said first material.

16. A process according to claim 15, comprising the step of:
sputtering said first material and said second material as double targets so as to laminate said intermediate layer which is formed by said first material and said second material, on said substrate; and
sputtering said first material as a single target so as to laminate said one electrode layer which is formed by said first material on said intermediate layer.
